(19) United States
(12) Patent Application Publication
(10) Pub. No.: US 2024/0106435 A1
(43) Pub. Date: Mar. 28, 2024

(54) LEVEL SHIFT CIRCUIT

(71) Applicant: Shanghai Huali Integrated Circuit Corporation, Shanghai (CN)

(72) Inventors: Li ZHANG, Shanghai (CN); Ge LI, Shanghai (CN); Junhui PU, Shanghai (CN)

(21) Appl. No.: 18/181,875

(22) Filed: Mar. 10, 2023

(30) Foreign Application Priority Data
Sep. 28, 2022 (CN) 202211187635.8

(51) Int. Cl. H03K 19/0185

(52) U.S. Cl. CPC H03K 19/018521

(57) ABSTRACT

A level shift circuit comprises a pull-down circuit which includes a first sub-circuit and a second sub-circuit connected in series. A control end of the first sub-circuit is connected to a bias voltage. A first end of the first sub-circuit is connected to a high-voltage output end, and a second end is connected to a first end of the second sub-circuit. A second end of the second sub-circuit is connected to the ground and a control end provides a low-voltage input end. The voltage at the second end of the first sub-circuit changes with the bias voltage. The magnitude of the bias voltage is set such that the first sub-circuit is kept in a conducted state and the maximum voltage at the second end of the first sub-circuit is lower than or equal to the withstand voltage of the second sub-circuit.

### CROSS-REFERENCES TO RELATED APPLICATIONS

This application claims the priority to Chinese patent application No. CN 202211187635.8, filed on Sep. 28, 2022, and entitled “LEVEL SHIFT CIRCUIT”, the disclosure of which is incorporated herein by reference in its entirety.

### TECHNICAL FIELD

The present disclosure relates to a semiconductor integrated circuit (IC), and in particular to a level shift circuit.

### BACKGROUND

With the development of integrated circuits, the typical operating voltage inside an IC has been lower than 1.0V, with a minimum at 0.6V. Outside an IC chip, the power supply voltage can still be 1.8V, 2.5V, 3.3V, 5V or higher. To adapt to various application scenarios, a level shift circuit needs to be used to convert a low-voltage signal inside the IC into a corresponding high-voltage signal outside the IC, and convert a high-voltage signal outside the IC into a corresponding low-voltage signal inside the IC.

Referring to FIG. 1, it illustrates a circuit diagram of an existing first-type level shift circuit. FIG. 1 illustrates a traditional four-transistor level shift circuit, which includes a pair of high-voltage PMOS transistors P1 and P2, a pair of high-voltage NMOS transistors N1 and N2. The PMOS transistor P1 and the NMOS transistor N1 are connected in series between the first power supply voltage, i.e., the high voltage VH and the ground VSS. The PMOS transistor P2 and the NMOS transistor N2 are connected in series between the high voltage VH and the ground VSS. A gate of the PMOS transistor P1 is connected to drains of the NMOS transistor N2 and the PMOS transistor P2. A gate of the PMOS transistor P2 is connected to drains of the NMOS transistor N1 and the PMOS transistor P1. A PMOS transistor P3 and an NMOS transistor N3 of the phase inverter are connected in series between second power supply voltage, that is, low voltage VL and the ground VSS. An input signal IN_PL is connected to a gate of the NMOS transistor N1 and an input end of the phase inverter, i.e., gates of the PMOS transistor P3 and the NMOS transistor N3. An output end of the phase inverter, i.e., drains of the PMOS transistor P3 and the NMOS transistor N3 outputs IN_NL, and is connected to the gate of the NMOS transistor N2. A drain of the NMOS transistor N2 and a drain of the PMOS transistor P2 are connected together as an output end for an output signal OUTP. The output signal OUTP is further connected to a drain of the NMOS transistor N4. A gate of the NMOS transistor N4 is connected to a high-voltage control signal POC_PH. A source of the NMOS transistor N4 is connected to the ground. A connecting end between the drain of the NMOS transistor N1 and the drain of the PMOS transistor P1 is used as an output end for an output signal OUTN. The output signals OUTN and OUTP are a pair of reverse-phase signals. The gate of the NMOS transistor N4 is controlled by the high-voltage control signal POC_PH generated by a power supply detection circuit. When the low voltage VL is lower than predetermined voltage, the high-voltage control signal POC_PH is logically high, the NMOS transistor N4 is turned on, the output signal OUTP is pulled to a ground VSS potential, the PMOS transistor P1 is turned on at this time, and the output signal OUTN remains high voltage VH.

The existing first-type structure illustrated in FIG. 1 may have a situation that the threshold voltage (VT) of the high-voltage NMOS transistor N1 and the NMOS transistor N2 gets close to or even higher than the low voltage VL on some process platforms or those platforms with low internal voltage. In this case, the structure cannot realize reversal when used for level conversion. At this time, it is often necessary to use an existing second-type structure illustrated in FIG. 2.

Referring to FIG. 2, it illustrates a circuit diagram of an existing second-type level shift circuit. The existing second-type level shift circuit includes a pair of high-voltage PMOS transistors P1 and P2, a pair of low-voltage NMOS transistors N1 and N2, and a pair of high-voltage NMOS transistors N5 and N6. The high-voltage NMOS transistors N5 and N6 are both native NMOS transistors with threshold voltage tending to 0V, that is, the high-voltage NMOS transistors N5 and N6 are both native high-voltage NMOS transistors. The PMOS transistor P1 and the NMOS transistors N1 and N5 are connected in series between first power supply voltage, i.e., high voltage VH and the ground VSS. The PMOS transistor P2 and the NMOS transistors N2 and N6 are connected in series between the high voltage VH and the ground VSS. A gate of the PMOS transistor P1 is connected to a drain of the NMOS transistor N6 and a drain of the PMOS transistor P2. A gate of the PMOS transistor P2 is connected to drains of the NMOS transistor N5 and the PMOS transistor P1. A phase inverter formed by connecting the PMOS transistor P3 and the NMOS transistor N3 in series is connected between second power supply voltage, i.e., low voltage VL and the ground VSS. An input signal IN_PL is connected to gates of the NMOS transistors N1 and N5 and an input end of the phase inverter, i.e., a gate of the PMOS transistor P3 and a gate of the NMOS transistor N3. An output end of the phase inverter, i.e., drains of the PMOS transistor P3 and the NMOS transistor N3, as an input signal IN_NL after phase reversal, is connected to gates of the NMOS transistor N2 and N6. The drain of the NMOS transistor N6 and the drain of the PMOS transistor P2 are connected together as an output end for an output signal OUTP. The output signal OUTP is further connected to a drain of the NMOS transistor N4. A gate of the NMOS transistor N4 is connected to a high-voltage control signal POC_PH. A source of the NMOS transistor N4 is connected to the ground. A connecting end between a drain of the NMOS transistor N5 and a drain of the PMOS transistor P1 is used as an output end for an output signal OUTN. The output signals OUTN and OUTP are a pair of reverse-phase signals. In FIG. 2, an output end OUT of the level converter is connected to the ground VSS through the high-voltage NMOS transistor N4. The gate of the NMOS transistor N4 is controlled by the high-voltage control signal POC_PH generated by a power supply detection circuit. When the low voltage VL is lower than predetermined voltage, the high-voltage control signal POC_PH is logically high, the NMOS transistor N4 is turned on, the output signal OUTP is pulled to a ground VSS potential, the PMOS transistor P1 is turned on at this time, and the output signal OUTN remains high voltage VH.

The existing second-type structure illustrated in FIG. 2 uses the native high-voltage NMOS transistors with a threshold voltage close to 0V which are connected with the low-voltage NMOS transistors in series. The native high-voltage NMOS transistors, are NMOS transistors N5 and N6, and the low-voltage NMOS transistors are NMOS transistors N1 and N2. The level reversal problem of the existing first-type structure illustrated in FIG. 1 is solved by using the native high-voltage NMOS transistors and the low-voltage NMOS transistor with low threshold voltage or low withstand voltage (the withstand voltage is used as a measurement term and is related to the electrical insulation breakdown voltage). The withstand voltage problem of the low-voltage NMOS transistors is solved by using the native high-voltage NMOS transistors. However, many advanced process platforms lack native MOS devices, or need to increase the cost to add native MOS devices. For example, the high-voltage process or FINFET process lacks a process of including native MOS devices, so the existing second-type structure illustrated in FIG. 2 cannot be used in the high-voltage process or the FINFET process. If the native high-voltage NMOS transistors N5 and N6 are replaced with high-voltage NMOS transistors, when the threshold voltage VT of the high-voltage NMOS transistors is close to or even higher than the low voltage VL, there is still the problem that the level cannot be reversed.

### BRIEF SUMMARY

According to some embodiments in this present disclosure, a level shift circuit present disclosure includes:
a pull-up circuit and a pull-down circuit connected between the first power supply voltage and the ground;
a low-voltage input end of the pull-down circuit is connected to a low-voltage input signal, a connecting point between the pull-up circuit and the pull-down circuit is a high-voltage output end and outputs a high-voltage output signal, the magnitude of the low-voltage input signal is between the second power supply voltage and the ground, and the magnitude of the high-voltage output signal is between the first power supply voltage and the ground; the first power supply voltage is higher than the second power supply voltage;
the pull-down circuit includes a first sub-circuit and a second sub-circuit connected in series;
the withstand voltage of the first sub-circuit is higher than or equal to the first power supply voltage;
the withstand voltage of the second sub-circuit is higher than or equal to the second power supply voltage and the withstand voltage of the second sub-circuit is lower than the first power supply voltage;
a control end of the first sub-circuit is connected to bias voltage, a first end of the first sub-circuit is connected to the high-voltage output end, and a second end of the first sub-circuit is connected to a first end of the second sub-circuit;
a second end of the second sub-circuit is connected to the ground and a control end of the second sub-circuit is the low-voltage input end; and
the voltage at the second end of the first sub-circuit changes with the bias voltage; the magnitude of the bias voltage is set such that the first sub-circuit is kept in a conducted state and make the maximum voltage at the second end of the first sub-circuit is lower than or equal to the withstand voltage of the second sub-circuit.

In some cases, the first sub-circuit includes a first NMOS transistor;
the first end of the first sub-circuit includes a drain of the first NMOS transistor;
the second end of the first sub-circuit includes a source of the first NMOS transistor;
the control end of the first sub-circuit includes a gate of the first NMOS transistor;
the first NMOS transistor has first threshold voltage; and
the maximum source voltage of the first NMOS transistor is equal to the bias voltage minus the first threshold voltage.

In some cases, the second sub-circuit includes a second NMOS transistor;
the first end of the second sub-circuit includes a drain of the second NMOS transistor and the drain of the second NMOS transistor is connected to the source of the first NMOS transistor;
the second end of the second sub-circuit includes a source of the second NMOS transistor and the source of the second NMOS transistor is connected to the ground;
the control end of the second sub-circuit includes a gate of the second NMOS transistor, the gate of the second NMOS transistor is used as a first low-voltage input end, and the first low-voltage input end inputs a first low-voltage input signal.

In some cases, the bias voltage is provided by a bias circuit and the bias circuit includes a current source and a first PMOS transistor;
the withstand voltage of the first PMOS transistor is higher than or equal to the first power supply voltage;
the current source is connected between the first power supply voltage and the source of the first PMOS transistor;
the gate of the first PMOS transistor is connected to the second power supply voltage;
the drain of the first PMOS transistor is connected to the ground;
the first PMOS transistor has second threshold voltage;
the source of the first PMOS transistor outputs the bias voltage, and the magnitude of the bias voltage is equal to the second power supply voltage plus an absolute value of the second threshold voltage.

In some cases, the pull-up circuit includes a second PMOS transistor;
a source of the second PMOS transistor is connected to the first power supply voltage;
a drain of the second PMOS transistor is connected to the drain of the first NMOS transistor.

In some cases, both the pull-up circuit and the pull-down circuit are differential structures.

In some cases, the pull-up circuit further includes a third PMOS transistor;
a source of the third PMOS transistor is connected to the first power supply voltage;
a gate of the third PMOS transistor is connected to the drain of the second PMOS transistor, and the drain of the second PMOS transistor is a first high-voltage output end and outputs a first high-voltage output signal;
a gate of the second PMOS transistor is connected to a drain of the third PMOS transistor, and the drain of the third PMOS transistor is a second high-voltage output end and outputs a second high-voltage output signal; and
the first high-voltage output signal and the second high-voltage output signal are in a reverse phase.

In some cases, the first sub-circuit further includes a third NMOS transistor;
the first end of the first sub-circuit further includes a drain of the third NMOS transistor;
the second end of the first sub-circuit further includes a source of the third NMOS transistor;
the control end of the first sub-circuit further includes a gate of the third NMOS transistor;
the third NMOS transistor has the first threshold voltage; and
the maximum source voltage of the third NMOS transistor is equal to the bias voltage minus the first threshold voltage.

In some cases, the second sub-circuit further includes a fourth NMOS transistor;
the first end of the second sub-circuit further includes a drain of the fourth NMOS transistor, and the drain of the fourth NMOS transistor is connected to the source of the third NMOS transistor;
the second end of the second sub-circuit further includes a source of the fourth NMOS transistor and the source of the fourth NMOS transistor is connected to the ground;
the control end of the second sub-circuit further includes a gate of the fourth NMOS transistor, the gate of the fourth NMOS transistor is used as a second low-voltage input end, and the second low-voltage input end inputs a second low-voltage input signal; and the second low-voltage input signal and the first low-voltage input signal are in a reverse phase.

In some cases, the level shift circuit further includes a phase inverter formed by connecting a fourth PMOS transistor and a fifth NMOS transistor, a source of the fourth PMOS transistor is connected to the second power supply voltage, a source of the fifth NMOS transistor is connected to the ground, a gate of the fourth PMOS transistor and a gate of the fifth NMOS transistor are connected to the first low-voltage input signal, and a drain of the fourth PMOS transistor and a drain of the fifth NMOS transistor are connected together and output the second low-voltage input signal.

In the present disclosure, the pull-down circuit of the level shift circuit includes the first sub-circuit with high withstand voltage and the second sub-circuit with low withstand voltage. The difference from the existing circuit is that the control end of the first sub-circuit is controlled through the low-voltage input signal, but the control end of the first sub-circuit in the present disclosure is controlled through the additionally set bias voltage. The bias voltage can ensure that the first sub-circuit is conducted and the maximum voltage at the second end of the first sub-circuit is lower than or equal to the withstand voltage of the second sub-circuit at the same time, thus ensuring the withstand voltage meet the requirement of the second sub-circuit. Since the second sub-circuit has low withstand voltage and the first sub-circuit can realize conduction under the control of the bias voltage, the present disclosure can enable the circuit realize the normal level reversal under the condition that the second power supply voltage is continuously reduced. For example, when the second power supply voltage is lower than the threshold voltage of the MOS device with high withstand voltage in the pull-down circuit, the pull-down circuit can also be conducted to realize level signal reversal. Therefore, it is not necessary to set the native high-voltage MOS transistors with threshold voltage tending to 0V in the pull-down circuit, thus eliminating the problem of high process cost caused by the arrangement of the native high-voltage MOS transistors and eliminating the restriction on the process platform caused by the use of the native high-voltage MOS devices. Therefore, the present disclosure further has the advantages of low cost and high applicability to various process platforms.

### BRIEF DESCRIPTION OF THE DRAWINGS

The present disclosure will be further described in detail below in combination with the specific embodiments with reference to the drawings.

FIG. 1 illustrates a circuit diagram of an existing first-type level shift circuit.

FIG. 2 illustrates a circuit diagram of an existing second-type level shift circuit.

FIG. 3 illustrates a circuit diagram of a level shift circuit according to an embodiment of the present disclosure.

FIG. 4 illustrates a diagram of a bias circuit adopted in a level shift circuit according to an embodiment of the present disclosure.

FIG. 5 illustrates simulation curves of voltage at a second end of a first sub-circuit of a level shift circuit according to an embodiment of the present disclosure.

FIG. 6 illustrates a simulation curve of a second high-voltage output signal of a level shift circuit according to an embodiment of the present disclosure.

### DETAILED DESCRIPTION OF THE APPLICATION

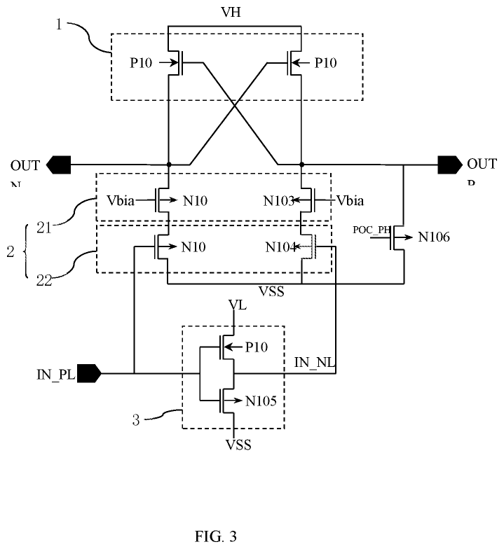

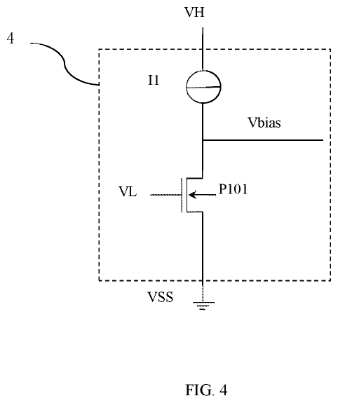

FIG. 3 illustrates a circuit diagram of a level shift circuit according to an embodiment of the present disclosure. FIG. 4 illustrates a diagram of a bias circuit 4 adopted in a level shift circuit according to an embodiment of the present disclosure. The level shift circuit according to the embodiment of the present disclosure includes:
a pull-up circuit 1 and a pull-down circuit 2 connected between the first power supply voltage VH and the ground VSS.

A low-voltage input end of the pull-down circuit 2 is connected to a low-voltage input signal. A connecting point between the pull-up circuit 1 and the pull-down circuit 2 is a high-voltage output end and outputs a high-voltage output signal. The magnitude of the low-voltage input signal is between the second power supply voltage VL and the ground VSS. The magnitude of the high-voltage output signal is between the first power supply voltage VH and the ground VSS. The first power supply voltage VH, named high voltage, is higher than the second power supply voltage VL, named low voltage.

The pull-down circuit 2 includes a first sub-circuit 21 and a second sub-circuit 22 connected in series.

The withstand voltage of the first sub-circuit 21 is higher than or equal to the first power supply voltage VH. Therefore, the operating voltage of the first sub-circuit 21 adopts the higher first power supply voltage VH.

The withstand voltage of the second sub-circuit 22 is higher than or equal to the second power supply voltage VL and the withstand voltage of the second sub-circuit 22 is lower than the first power supply voltage VH. Therefore, the operating voltage of the second sub-circuit 22 adopts the lower second power supply voltage VL.

A control end of the first sub-circuit 21 is connected to bias voltage Vbias. A first end of the first sub-circuit 21 is connected to the high-voltage output end. A second end of the first sub-circuit 21 is connected to a first end of the second sub-circuit 22.

A second end of the second sub-circuit 22 is connected to the ground VSS and a control end of the second sub-circuit 22 is the low-voltage input end.

The voltage at the second end of the first sub-circuit 21 changes with the bias voltage Vbias. The magnitude of the bias voltage Vbias is such set that the first sub-circuit 21 is kept in a conducted state and the maximum voltage at the second end of the first sub-circuit 21 is lower than or equal to the withstand voltage of the second sub-circuit.

In the embodiment of the present disclosure, the first sub-circuit 21 includes a first NMOS transistor N101.

The first end of the first sub-circuit 21 includes a drain of the first NMOS transistor N101.

The second end of the first sub-circuit 21 includes a source of the first NMOS transistor N101.

The control end of the first sub-circuit 21 includes a gate of the first NMOS transistor N101.

The first NMOS transistor N101 has first threshold voltage.

The maximum source voltage of the first NMOS transistor N101 is equal to the bias voltage Vbias minus the first threshold voltage.

The second sub-circuit 22 includes a second NMOS transistor N102.

The first end of the second sub-circuit 22 includes a drain of the second NMOS transistor N102 and the drain of the second NMOS transistor N102 is connected to the source of the first NMOS transistor N101.

The second end of the second sub-circuit 22 includes a source of the second NMOS transistor N102 and the source of the second NMOS transistor N102 is connected to the ground VS S.

The control end of the second sub-circuit 22 includes a gate of the second NMOS transistor N102, the gate of the second NMOS transistor N102 is used as a first low-voltage input end, and the first low-voltage input end inputs a first low-voltage input signal IN_PL.

The pull-up circuit 1 includes a second PMOS transistor P102.

A source of the second PMOS transistor P102 is connected to the first power supply voltage VH.

A drain of the second PMOS transistor P102 is connected to the drain of the first NMOS transistor N101.

In the embodiment of the present disclosure, both the pull-up circuit 1 and the pull-down circuit 2 are differential structures.

The pull-up circuit 1 further includes a third PMOS transistor P103.

A source of the third PMOS transistor P103 is connected to the first power supply voltage VH.

A gate of the third PMOS transistor P103 is connected to the drain of the second PMOS transistor P102. The drain of the second PMOS transistor P102 is a first high-voltage output end and outputs a first high-voltage output signal OUTN.

A gate of the second PMOS transistor P102 is connected to a drain of the third PMOS transistor P103. The drain of the third PMOS transistor P103 is a second high-voltage output end and outputs a second high-voltage output signal OUTP.

The first high-voltage output signal OUTN and the second high-voltage output signal OUTP are in reverse phase.

The first sub-circuit 21 further includes a third NMOS transistor N103.

The first end of the first sub-circuit 21 further includes a drain of the third NMOS transistor N103.

The second end of the first sub-circuit 21 further includes a source of the third NMOS transistor N103.

The control end of the first sub-circuit 21 further includes a gate of the third NMOS transistor N103.

The third NMOS transistor N103 has the first threshold voltage.

The maximum source voltage of the third NMOS transistor N103 is equal to the bias voltage Vbias minus the first threshold voltage.

The second sub-circuit 22 further includes a fourth NMOS transistor N104.

The first end of the second sub-circuit further 22 includes a drain of the fourth NMOS transistor N104. The drain of the fourth NMOS transistor N104 is connected to the source of the third NMOS transistor N103.

The second end of the second sub-circuit 22 further includes a source of the fourth NMOS transistor N104. The source of the fourth NMOS transistor N104 is connected to the ground VSS.

The control end of the second sub-circuit 22 further includes a gate of the fourth NMOS transistor N104. The gate of the fourth NMOS transistor N104 is used as a second low-voltage input end. The second low-voltage input end inputs a second low-voltage input signal IN_NL. The second low-voltage input signal IN_NL and the first low-voltage input signal IN_PL are in reverse phase.

The level shift circuit further includes a phase inverter 3 formed by connecting a fourth PMOS transistor P104 and a fifth NMOS transistor N105. A source of the fourth PMOS transistor P104 is connected to the second power supply voltage VL. A source of the fifth NMOS transistor N105 is connected to the ground VSS. A gate of the fourth PMOS transistor P104 and a gate of the fifth NMOS transistor N105 are connected to the first low-voltage input signal IN_PL. A drain of the fourth PMOS transistor P104 and a drain of the fifth NMOS transistor N105 are connected together and output the second low-voltage input signal IN_NL.

The bias voltage Vbias is provided by a bias circuit 4. The bias circuit 4 includes a current source Il and a first PMOS transistor P101.

The withstand voltage of the first PMOS transistor P101 is higher than or equal to the first power supply voltage VH.

The current source Il is connected between the first power supply voltage VH and the source of the first PMOS transistor P101.

The gate of the first PMOS transistor P101 is connected to the second power supply voltage VL.

The drain of the first PMOS transistor P101 is connected to the ground VSS.

The first PMOS transistor P101 has second threshold voltage.

The source of the first PMOS transistor P101 outputs the bias voltage Vbias. The magnitude of the bias voltage Vbias is equal to the second power supply voltage VL plus an absolute value of the second threshold voltage. The absolute value of the second threshold voltage is close to the first threshold voltage, which is determined by the process.

The level shift circuit further includes a sixth NMOS transistor N106. A drain of the sixth NMOS transistor N106 is connected to the second high-voltage output end. A source of the sixth NMOS transistor N106 is connected to the ground VSS. A gate of the sixth NMOS transistor N106 is connected to first control voltage POC_PH.

When the second power supply voltage VL is lower than the predetermined voltage, the first control voltage POC_PH is high-level, so that the second high-voltage output signal OUTP is fixedly connected to the ground VSS and the first high-voltage output signal OUTN is fixedly connected to the first power supply voltage VH.

When the second power supply voltage VL is higher than or equal to the predetermined voltage, the sixth NMOS transistor N106 is disconnected.

In the embodiment of the present disclosure, the pull-down circuit 2 of the level shift circuit includes the first sub-circuit 21 with high withstand voltage and the second sub-circuit 22 with low withstand voltage. Different from that the control end of the first sub-circuit 21 in the existing circuit is controlled through the low-voltage input signal, the control end of the first sub-circuit 21 in the embodiment of the present disclosure is controlled through the additionally set bias voltage Vbias. The bias voltage Vbias can ensure that the first sub-circuit 21 is conducted and the maximum voltage at the second end of the first sub-circuit 21 is lower than or equal to the withstand voltage of the second sub-circuit 22 at the same time, thus ensuring the withstand voltage requirement of the second sub-circuit 22. Since the second sub-circuit 22 has low withstand voltage and the first sub-circuit 21 can realize conduction under the control of the bias voltage Vbias, the embodiment of the present disclosure can make the circuit to realize the normal level reversal under the condition that the second power supply voltage VL is continuously reduced. For example, when the second power supply voltage VL is lower than the threshold voltage of the MOS device with high withstand voltage in the pull-down circuit 2, the pull-down circuit 2 can also be conducted to realize level signal reversal. That is, even if the low voltage VL is lower than the first threshold voltage of the high-voltage NMOS transistors N1 and N3, the NMOS transistors N1 and N3 can still be turned on without replacing the high-voltage NMOS transistors N1 and N3 by using the native high-voltage NMOS transistors with threshold voltage of 0V to make the paths corresponding to the high-voltage NMOS transistors N1 and N3 to be conducted. Therefore, it is not necessary to set the native high-voltage MOS transistors in the embodiment of the present disclosure, thus eliminating the problem of high process cost caused by the arrangement of the native high-voltage MOS transistors and eliminating the restriction on the process platform caused by the use of the native high-voltage MOS devices. Therefore, the embodiment of the present disclosure further has the advantages of low cost and high applicability to various process platforms.

In the structure provided by the embodiment of the present disclosure, when the first PMOS transistor P101 is turned on, the magnitude of the bias voltage Vbias is (VL+|VT|), where VT is the threshold voltage of the first PMOS transistor P101, that is, the second threshold voltage. Here VL represents the second power supply voltage.

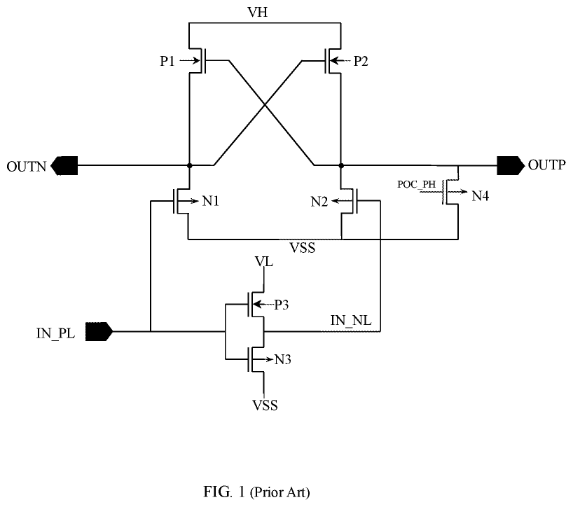

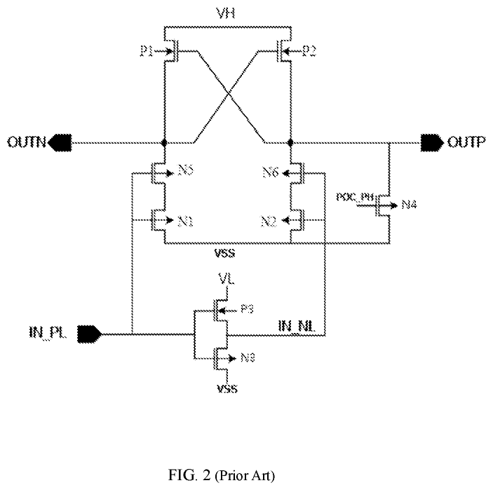

Vbias is connected to the gates of the first NMOS transistor N101 and the third NMOS transistor N103, and is subject to a loss of the threshold voltage of one NMOS transistor, that is, the first threshold voltage, so that the drain voltage range of the second NMOS transistor N102 and the fourth NMOS transistor N104 is 0V-VL. Compared with the existing first-type structure illustrated in FIG. 1, the embodiment of the present disclosure solves the withstand voltage problem of the low-voltage devices. Moreover, when the second NMOS transistor N102 and the fourth NMOS transistor N104 are turned on, the voltage difference between the source and drain is normal operating voltage VL, which will not inhibit the device performance of the second NMOS transistor N102 and the fourth NMOS transistor N104. Compared with the existing second-type structure illustrated in FIG. 2, the embodiment of the present disclosure solves the problem that it's difficult to reverse the level since the second NMOS transistor N102 and the fourth NMOS transistor N104 cannot work due to the restriction of the threshold voltage of the high-voltage NMOS.

Taking the 28 nm platform as an example, full PVT (Process, Voltage, Temperature) process corner simulation is performed by using VL of 0.9V and VH of 8V.

FIG. 5 illustrates the simulation curves of the voltage at the second end of the first sub-circuit of the level shift circuit according to the embodiment of the present disclosure. The second end of the first sub-circuit includes the source of the first NMOS transistor N101 and the source of the third NMOS transistor N103. Curve 101 is the simulation curve of the source voltage of the first NMOS transistor N101, i.e., the simulation curve of the drain voltage of the second NMOS transistor N102. Curve 102 is the simulation curve of the source voltage of the third NMOS transistor N103, i.e., the simulation curve of the drain voltage of the fourth NMOS transistor N104.

Curves 101 and 102 are overlapped traces from multiple simulations. It can be seen that when N102/N104, i.e., the second NMOS transistor N102 and the fourth NMOS transistor N104 are turned off, the corresponding drain voltage value is between 0.5V-1.1*VL, which solves the withstand voltage problem of the low-voltage devices, i.e., the second NMOS transistor N102 and the fourth NMOS transistor N104. Moreover, the voltage difference between the source and the drain is greater than the threshold voltage of the low-voltage NMOS devices, it also ensures the normal device operation performance of the second NMOS transistor N102 and the fourth NMOS transistor N104, and solves the problem that it is difficult to reverse the level.

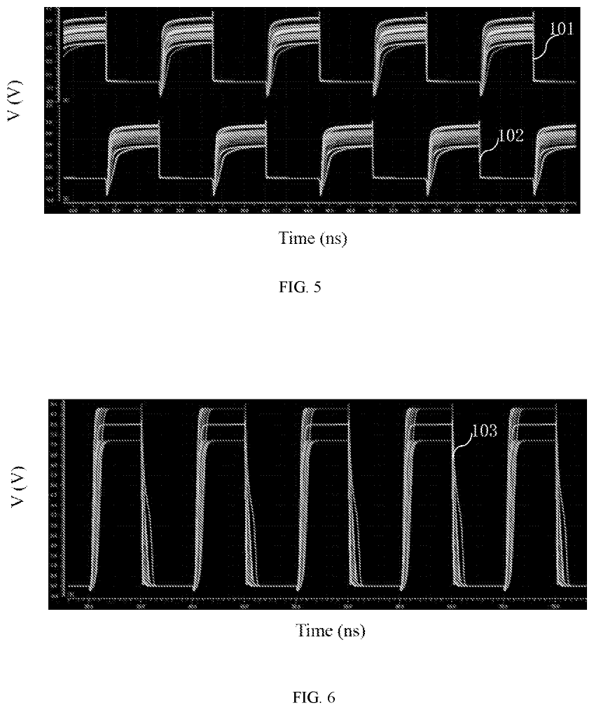

FIG. 6 illustrates simulation curves 103 of the second high-voltage output signal OUTP of the level shift circuit according to the embodiment of the present disclosure. The curves 103 are overlapped traces from multiple simulations. It can be seen that the voltage output of the second high-voltage output signal OUTP is normal. Therefore, in the embodiment of the present disclosure, the problem that it is difficult to realize 0.9V-8V full corner reversal has been solved.

The present disclosure has been described in detail through the specific embodiments above, which, however, do not constitute limitations to the present disclosure. Without departing from the principle of the present disclosure, those skilled in the art may also make many changes and improvements, which should also be considered as falling within the scope of protection of the present disclosure.

What is claimed is:

1. A level shift circuit, comprising:
a pull-up circuit and a pull-down circuit, wherein the pull-up circuit and the pull-down circuit are connected between a first power supply voltage and a ground
wherein a low-voltage input end of the pull-down circuit is connected to a low-voltage input signal,
wherein the pull-up circuit and the pull-down circuit connect at a high-voltage output end, wherein the high-voltage output end outputs a high-voltage output signal,
wherein a magnitude of the low-voltage input signal is between a second power supply voltage and a voltage of the ground, and a magnitude of the high-voltage output signal is between the first power supply voltage and the voltage of the ground; wherein the first power supply voltage is higher than the second power supply voltage;
wherein the pull-down circuit comprises a first sub-circuit and a second sub-circuit, wherein the first sub-circuit and the second sub-circuit are connected in series;
wherein a withstand voltage of the first sub-circuit is higher than or equal to the first power supply voltage;
wherein the withstand voltage of the second sub-circuit is higher than or equal to the second power supply voltage and lower than the first power supply voltage;
wherein a control end of the first sub-circuit is connected to a bias voltage, a first end of the first sub-circuit is connected to the high-voltage output end, and a second end of the first sub-circuit is connected to a first end of the second sub-circuit;
wherein a second end of the second sub-circuit is connected to the ground and a control end of the second sub-circuit is the low-voltage input end; and
wherein a voltage at the second end of the first sub-circuit changes with the bias voltage;
wherein a magnitude of the bias voltage is set such that the first sub-circuit is kept in a conducted state and a maximum voltage at the second end of the first sub-circuit is lower than or equal to the withstand voltage of the second sub-circuit.

2. The level shift circuit according to claim 1, wherein the first sub-circuit comprises a first NMOS transistor;
wherein the first end of the first sub-circuit comprises a drain of the first NMOS transistor;
wherein the second end of the first sub-circuit comprises a source of the first NMOS transistor;
wherein the control end of the first sub-circuit comprises a gate of the first NMOS transistor;
wherein the first NMOS transistor has a first threshold voltage; and
wherein a maximum source voltage of the first NMOS transistor is equal to the bias voltage minus the first threshold voltage.

3. The level shift circuit according to claim 1, wherein the second sub-circuit comprises a second NMOS transistor;
wherein the first end of the second sub-circuit comprises a drain of the second NMOS transistor, wherein the drain of the second NMOS transistor is connected to the source of the first NMOS transistor; and
wherein the second end of the second sub-circuit comprises a source of the second NMOS transistor, wherein the source of the second NMOS transistor is connected to the ground;
wherein the control end of the second sub-circuit comprises a gate of the second NMOS transistor, wherein the gate of the second NMOS transistor provides a first low-voltage input end, and wherein the first low-voltage input end inputs a first low-voltage input signal.

4. The level shift circuit according to claim 3, wherein the bias voltage is provided by a bias circuit, wherein the bias circuit comprises a current source and a first PMOS transistor;
wherein the withstand voltage of the first PMOS transistor is higher than or equal to the first power supply voltage;
wherein the current source is connected between the first power supply voltage and a source of the first PMOS transistor;
wherein a gate of the first PMOS transistor is connected to the second power supply voltage;
wherein a drain of the first PMOS transistor is connected to the ground;
wherein the first PMOS transistor has a second threshold voltage; and
wherein the source of the first PMOS transistor outputs the bias voltage, wherein the magnitude of the bias voltage is equal to the second power supply voltage plus an absolute value of the second threshold voltage.

5. The level shift circuit according to claim 4, wherein the pull-up circuit comprises a second PMOS transistor;
wherein a source of the second PMOS transistor is connected to the first power supply voltage; and
wherein a drain of the second PMOS transistor is connected to the drain of the first NMOS transistor.

6. The level shift circuit according to claim 5, wherein each of the pull-up circuit and the pull-down circuit comprises a differential structure.

7. The level shift circuit according to claim 6, wherein the pull-up circuit further comprises
a third PMOS transistor;
wherein a source of the third PMOS transistor is connected to the first power supply voltage;
wherein a gate of the third PMOS transistor is connected to the drain of the second PMOS transistor, and wherein the drain of the second PMOS transistor provides a first high-voltage output end and outputs a first high-voltage output signal;
wherein a gate of the second PMOS transistor is connected to a drain of the third PMOS transistor, wherein the drain of the third PMOS transistor provides a second high-voltage output end and outputs a second high-voltage output signal; and
wherein the first high-voltage output signal and the second high-voltage output signal are in reverse phase.

8. The level shift circuit according to claim 7,
wherein the first sub-circuit further comprises a third NMOS transistor;
wherein the first end of the first sub-circuit further comprises a drain of the third NMOS transistor;
wherein the second end of the first sub-circuit further comprises a source of the third NMOS transistor;
wherein the control end of the first sub-circuit further comprises a gate of the third NMOS transistor;
wherein the third NMOS transistor has the first threshold voltage; and
wherein a maximum source voltage of the third NMOS transistor is equal to the bias voltage minus the first threshold voltage.

9. The level shift circuit according to claim 8, wherein the second sub-circuit further comprises a fourth NMOS transistor;
wherein the first end of the second sub-circuit further comprises a drain of the fourth NMOS transistor, wherein the drain of the fourth NMOS transistor is connected to the source of the third NMOS transistor;
wherein the second end of the second sub-circuit further comprises a source of the fourth NMOS transistor, wherein the source of the fourth NMOS transistor is connected to the ground;
wherein the control end of the second sub-circuit further comprises a gate of the fourth NMOS transistor, wherein the gate of the fourth NMOS transistor provides a second low-voltage input end, wherein the second low-voltage input end inputs a second low-voltage input signal; and
wherein second low-voltage input signal and the first low-voltage input signal are in reverse phase.

10. The level shift circuit according to claim 9, further comprising: a phase inverter formed by connecting a fourth PMOS transistor and a fifth NMOS transistor, wherein a source of the fourth PMOS transistor is connected to the second power supply voltage, wherein a source of the fifth NMOS transistor is connected to the ground, wherein a gate of the fourth PMOS transistor and a gate of the fifth NMOS transistor are connected to the first low-voltage input signal, and wherein a drain of the fourth PMOS transistor and a drain of the fifth NMOS transistor are connected together to output the second low-voltage input signal.
